(19) United States
(12) Patent Application Publication
(10) Pub. No.: US 2008/0193684 A1
(43) Pub. Date: Aug. 14, 2008

(54) Method for Producing Grained Plastic Moldings and Plastic Moldings

(75) Inventors: Jurgen Buhring, Goppingen (DE); Volker Hulsewede, Goppingen (DE)

Correspondence Address: LERNER GREENBERG STEMER LLP, P O BOX 2480, HOLLYWOOD, FL, 33022-2480, US

(73) Assignee: BENECKE-KALIKO AG, Hannover (DE)

(21) Appl. No.: 12/105,036

(22) Filed: Apr. 17, 2008

Related U.S. Application Data
(63) Continuation of application No. PCT/EP2006/066564, filed on Sep. 21, 2006.

(30) Foreign Application Priority Data
Oct. 27, 2005 (DE) 10 2005 051 392.1

(51) Int. Cl. H01J 37/30; B29C 43/02; B29C 43/52; B29C 59/02; B32B 27/32; B32B 3/26; B32B 33/00; B32B 3/02

(52) U.S. Cl. 428/31; 264/293; 264/322; 264/479; 264/485; 428/141; 428/523; 428/304.4

(57) ABSTRACT

A method for producing plastic moldings with a distinct grain/three-dimensional surface structure by grain-imparting negative thermoforming. The plastic molding is subjected to a preheating, and the molding is then pressed into/onto a negative mold that is formed with the negative of the three-dimensional surface structure to be applied. Those portions of the plastic molding that face away from the grain side are subjected to electron beam crosslinking before or during the preheating and the grain-imparting negative thermoforming.

### CROSS-REFERENCE TO RELATED APPLICATIONS

This is a continuation, under 35 U.S.C. § 120, of copending international application PCT/EP2006/066564, filed Sep. 21, 2006, which designated the United States; this application also claims the priority, under 35 U.S.C. § 119, of German patent application No. DE 10 2005 051 392.1, filed Oct. 27, 2005; the prior applications are herewith incorporated by reference in their entirety.

### BACKGROUND OF THE INVENTION

1. Field of the Invention

The invention relates to a process for the production of thermoformable plastics moldings coming directly from the mold with a three-dimensional surface structure, in particular of molded polymer skins or, respectively, foils with a grain on the surface by the in-mold-graining process. The plastics molding is subject to preheating up to a temperature where the plastics molding becomes capable of thermoplastic deformation, and where the plastics molding, a particular example being a plastics foil, is then pressed into/onto a female tool by means of subatmospheric pressure and/or of molding tools. The surface of the female tool comprises the negative of the three-dimensional surface structure to be applied. The result is that the plastics molding not only receives the desired geometric shape but also is embossed with the desired positive surface structure. A plastics molding of this type is likewise described.

The prior art discloses processes for the production of thermoformable plastics moldings coming directly from the mold with a three-dimensional surface structure, in particular in the production of molded skins, for example for dashboards of motor vehicles. Various sintering or spraying processes may be mentioned in this context, where one or more liquid or pulverulent components are charged to a mold where they complete their reaction/hardening. Mention may also be made, however, of processes for the production of slush skins via rotational sintering, etc.

In the field of automotive interior design, a marked trend can be observed toward improvement in perceived quality. A consequence of this trend is that many typical foil applications within the decorative sector have been replaced by molded skins coming directly from the mold. A particularly attractive possibility here is establishment of the surface structure/surface texture, i.e. the surface of the molded skin, an example being a grained appearance, and the geometry of the entire component in a single molding process during the production process. To this end, by way of example, the grain structure and component geometry is introduced in negative form into a mold, and the mold skin is formed by sintering processes or spraying processes, and then removed. After a subsequent reverse-foaming process, the product is a three-dimensional component whose grain structure corresponds to the grain introduced within the mold. The reverse-foaming process here represents only one possibility of generating a support structure for the molded skin. Another example likewise known is adhesive bonding to apply structural support elements composed of hard plastics.

A requirement placed upon the materials used in the sintering processes and spraying processes, in order to permit good reproduction of the grain, is that they either have been treated to give a powder and have good flowability or that they are viscous liquids. This places restrictions on the usefulness of many classes of polymers in these processes. This in particular also applies to high-viscosity polyolefinic materials.

The manufacturing costs for production of mold skins produced by the spray-molding process or powder-sintering process are moreover relatively high. Some producers of door side parts and of instrument panels have therefore promoted the in-mold graining process in recent years, a specialized process which has developed from the female-mold thermoforming process. This in-mold-graining process can also be described as the female-mold graining and thermoforming process, this being the term used hereinafter.

Unlike standard thermoforming processes, where molding of the three-dimensional geometric structure of the component takes place by contact between the foil and a male thermoforming mold which generates the subsequent shape of the component, female-mold thermoforming draws a foil into a female mold, for example by using a vacuum. The female-mold graining and thermoforming process is then a particular embodiment of female-mold thermoforming where not only the geometric structure of the component but also the subsequent grain structure is introduced in negative form into the surface of the mold.

The requirement placed upon the starting material is accordingly different in the standard thermoforming process, in the female-mold thermoforming process, and in the female-mold graining and thermoforming process. Unlike the starting material for the two first-mentioned processes, that part of the foil facing toward the mold side in the female-mold graining and thermoforming process has to be of low viscosity, in order to ensure ideal reproduction of grain. However, that part of the foil must moreover also be thermally stable, in order to comply with the aging requirements and the requirements for heat resistance during subsequent use.

In the female-mold graining and thermoforming process, an unembossed foil is heated and then drawn by means of vacuum into a three-dimensional mold which comprises the desired grain image in negative form. A problem with the processes known hitherto in the prior art is that of converting the resultant grained foil to its geometric shape/the geometric shape of the component by a subsequent forming process, without distorting the grain image.

In order to obtain good transfer of the grain from the mold to the plastics foil used as starting material for the purposes of surface vacuum-forming in the female-mold graining and thermoforming process, it is important that the viscosity of the material has been minimized in the region of the processing temperature, which is typically beyond the melt temperature of the formulation components for the foil. This ensures good flow of the foil composition into the cavities of the mold. To this end, the foil, which usually takes the form of rolls, is removed from the roll and conducted, under slight tension, past a suitable heat source.

However, under these conditions the stability of the foil often becomes so low that the foil elongates during the heating cycle and sags noticeably. A possible consequence of this is that when the foil is placed in the mold, for example, an increased number of creases can arise on the component, or an increased number of thin areas in the foil.

In a procedure where the arrangement has the mold above the foil, and the foil is subjected to suction by a vacuum applied between mold and foil, a possible consequence of excessive sag of the foil is that the distance traversed before application to the graining mold becomes too long, and the foil thus cools excessively.

To this end, there are known production processes such as those disclosed in published patent application US 2003/0197302 A1. There, there is described a foil constitution for moldings which in principle are also intended to be produced by the female-mold graining and thermoforming process, as described in that document by way of example (cf. page 2, [0018]). The description there is of a peroxide-containing foil constitution with polypropylene, ethylene copolymer, and low-density polyethylene in various percentage constitutions. Crosslinking by means of the peroxides is used in order to achieve sufficiently high viscosity.

However, when the suitability of that foil is considered for the female-mold graining and thermoforming process, a disadvantage is that crosslinking extends uniformly, giving high viscosity over the entire thickness of the foil. However, in order to permit good reproduction of surface structure, at least that portion of the foil or that region of the thickness of the foil that faces toward the mold has to be of low viscosity.

German published patent application DE 40 07 876 A1 discloses a process for the production of embossed plastics moldings where first the surface structure is produced in an embossing process and then the geometric shape of the component is thermoformed. The starting material on which this process is based is a foil produced from two different plastics layers. The surface structure is then embossed into its upper layer by appropriate molds. This upper layer differs from the underlayer in that it is composed of a plastic which cannot be crosslinked by electron beams. In the process disclosed here, this electron-beam crosslinking specifically follows the embossing procedure, the result being crosslinking of the lower layer, which may be said to be “cured,” and an increase in the heat resistance of this lower layer. The foil, now composed of an upper embossed layer and of a lower electron-beam-crosslinked layer, is then again heated, and is then shaped by thermoforming to give the geometric shape of the component. This method produces a “hard” supporting underlayer, which supports the “soft” embossed upper layer during the thermoforming process and prevents the grain or embossment on the upper layer from becoming blurred or impermissibly deformed.

Alongside the problems described above in the production of the embossment/of the grain, a disadvantage of this process is that the necessary sequencing of a plurality of steps in the process (heating—embossing—crosslinking—heating—thermoforming) leads to a relatively complicated production process. A relatively complicated production process is moreover also required for the raw material, a plastics foil composed of the different plastics layers mentioned.

### BRIEF SUMMARY OF THE INVENTION

It is accordingly an object of the invention to provide a method for producing grained plastic moldings and a corresponding molding, which overcome the above-mentioned disadvantages of the heretofore-known devices and methods of this general type and which provides for a low-cost production process for plastics moldings by the female-mold graining and thermoforming process, which allows the foil used to be heated until the low melt viscosity for the forming and surface-embossing process has been reached, without any excessive loss of foil stability, and without elongation and, for example, noticeable sag of the foil during the heating cycle, and which moreover can give good capability of reproduction even of complicated surface structures or complicated surface grains in the thermoforming mold, and which requires only a minimal number of steps in the process.

With the foregoing and other objects in view there is provided, in accordance with the invention, a method of producing thermoformable plastics moldings coming directly from the mold with a three-dimensional surface structure, such as molded polymer skins or foils with a surface grain. The method comprises:

preheating the plastics molding up to a temperature where the plastics molding becomes capable of thermoplastic deformation;

pressing the plastics molding into/onto a female tool, the female tool having a surface with a negative of the three-dimensional surface structure to be applied to the plastics molding, to thereby form the plastics molding into a desired geometric shape and to emboss a grain side of the plastics molding with the desired surface structure; and

subjecting the plastics molding to electron-beam crosslinking to thereby substantially crosslink only those parts of the plastics molding facing away from the grain side and that are therefore not embossed with the three-dimensional surface structure, or embossed only to a small extent.

Preferably, the plastics molding is subjected to the electron-beam crosslinking prior to or concurrently with the preheating step and/or the pressing step. The pressing step comprises molding the plastics molding into/onto the female tool by subjecting the plastic molding to a subatmospheric pressure and/or a molding tool.

In accordance with an added feature of the invention, the plastics molding is a layered product composed of one or more plastics foils each having a thickness between 0.4 mm and 4 mm. The one or more plastic foils have a mutually identical polymeric constitution.

In accordance with an added feature of the invention, the plastics molding has a gel content. Preferably, the gel content of that half of a foil web intended for embossing with the surface structure is at most 20%, preferably between 3% and 15%.

In a preferred embodiment of the invention, a total gel content of the foil or foils lies between 5% and 60%, preferably between 5% and 40%.

In accordance with a concomitant feature of the invention, a difference in the gel content between an upper half and a lower half of the foil is at least 5%, and preferably about 10%.

With the above and other objects in view there is also provided, in accordance with the invention, a plastics molding with a three-dimensional surface structure, the plastics molding, after preheating to a temperature rendering the plastics molding capable of thermoplastic deformation, having been pressed into/onto a female tool in a vacuum-forming process by application of a vacuum and/or of one or more molding tools, the female tool having a surface formed with a negative of the three-dimensional surface structure to be applied, and the result being that the plastics molding not only receives the desired geometric shape but also is embossed with the desired positive surface structure, the plastics molding comprising:

a plastics molding body composed of a thermoplastic elastomer or of a polyolefin mixture;

the plastics molding body having a geometric shape dictated by the female tool and a surface embossed with the three-dimensional surface structure defined by the female tool; the plastics molding body having at least one plastics layer cross-linked by electron-beam cross-linking prior to or during the preheating, the vacuum-forming process, or the surface-embossing process, the cross-linked plastics layer facing away from the surface of the plastics molding body embossed with the three-dimensional surface structure, and being substantially free of the embossed three-dimensional surface structure.

The plastics molding here is, during or prior to the preheating and the thermoforming or the surface embossing process, subjected to electron-beam crosslinking, which in essence crosslinks only those parts of the plastics molding which face away from the subsequent grain side and which therefore are not, or only to a small extent, embossed or provided with the three-dimensional surface structure. The crosslinking of the regions mentioned of the foil, i.e. in essence of the central and lower region of the plastics molding/region of the foil below the grain to be applied subsequently reduces the melt viscosity in this region in such a way as to permit almost any desired adjustment of the extent to which the foil sags.

Crosslinking of polymers is produced by generation of covalent bonds between the polymer chains. Crosslinking usually takes place via traditional vulcanization using elemental sulfur or silanes, via peroxide crosslinking, via crosslinking with electron beams, or via a combination of the processes. In electron-beam crosslinking, the free radicals which initiate the crosslinking process are produced by the action of high-energy radiation on the polymer molecules. The accelerated electrons here interact with the irradiated molecules. Elastic impacts transfer the kinetic energy of the electrons onto atoms bonded within the molecule. The atoms impacted are thus converted to a state of higher excitation. If the energy introduced is greater than the bonding energy of the covalent bonds, the bond is cleaved, giving free radicals, macroradicals, and ions.

The free radicals react in subsequent reactions with the molecules of the polymer chains, or with themselves, and lead not only to generation of covalent bonds between the individual chains but also to degradation of the macromolecules via chain cleavage. Chain cleavage and chain extension proceed in parallel. The type of polymer used and the processing conditions, such as radiation dose, type of radiation, temperature, etc. determine which reaction dominates. Adjustment of process parameters is therefore of key importance during electron-beam crosslinking. Since chain degradation also takes place, crosslinking of all of the polymer chains present with one another is not achievable. Although radiation crosslinking does not achieve complete crosslinking, it nevertheless has a great influence on major features of the irradiated polymers.

The crosslinking sites newly produced during crosslinking induced by electron beams inhibit the folding of the polymer chains. The degree of crystallinity is thus lowered, whereupon in particular there is a decline in mechanical strength and brittleness as degree of crystallinity falls, whereas toughness and the level of damping properties increase. However, the decline in strength expected when the degree of crystallinity is lowered does not actually occur in most instances. The reason for this is that the raised structural strength of the crosslinked amorphous regions more than compensates for the lower crystallinity. The cohesion forces between the crosslinked polymer chain segments are many times greater than in the uncrosslinked state, where the only effective interactions between the chains are van der Waal forces. Sliding and displacement of the polymer chains is rendered substantially more difficult by crosslinking. These changes are apparent by way of example in an increase in mechanical strength and in heat resistance.

Inhomogeneous distribution over the foil thickness of the newly produced crosslinking areas, i.e. of the crosslinking density or network density—by way of example expressed via the gel content as a known measure of crosslinking—can be achieved in that exposure of the foil to electron beams takes place either from one side or else from both sides.

In the case of single-sided irradiation, the region of maximum dose adsorption can be varied here via the selection of the acceleration voltage for the electrons, as a function of the thickness of the foil, thus defining the distribution of crosslinking density.

In the case of double-sided irradiation, the distribution of crosslinking density can moreover be influenced via the relationship between the doses applied, with variation of the respective acceleration voltage. These depend on the respective constitutions of the foils to be irradiated and have to be appropriately adjusted again for each chemical system.

Adjustment of the crosslinking parameters during electron-beam crosslinking therefore permits crosslinking primarily, for example, of that part of the foil which is not grained in the thermoforming process. A possible outcome here is that the lower part of the foil is likewise crosslinked to a small extent, the amount of crosslinking generated in the lower regions being so small, however, as not to restrict the ability to reproduce the grain structure introduced within the thermoforming mold.

Other features which are considered as characteristic for the invention are set forth in the appended claims.

Although the invention is described herein as embodied in a method for producing grained plastic moldings and a plastic molding, it is nevertheless not intended to be limited to the expressed details, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying examples.

### DETAILED DESCRIPTION OF THE INVENTION

In one advantageous embodiment, the plastics molding is a layered product composed of one or more plastics foils, the thickness of each of which is from 0.4 to 4 mm. This makes it even easier to adjust the depth of crosslinking.

In a further simplification of the production of the raw material, the polymeric constitution of the plastics foils is identical, so that production of the base material is substantially simplified and can be carried out at low cost.

In an advantageous adjustment of the amount of crosslinking of the foil, the gel content of that half of the foil web intended for embossing with the subsequent surface structure is at most 20%, preferably from 3 to 15%. In a particular method of achieving this, the total gel content of the foil is from 5 to 60%, preferably from 5 to 40%, and the difference in the gel content between the upper and lower half of the foil is at least 5%, preferably 10%. With this, the viscosity of those regions of the foil facing toward the surface of the female mold is sufficiently low to achieve good embossment of the surface structure/grain structure, while that other half of the foil that has the higher gel content provides sufficient strength to permit production in a reliable process.

Gel content is usually determined by way of an extraction method, in which specimens are first cut in squares with an edge length of about 1.0 mm, at a thickness of about 0.5 mm. The specimens (about 100 mg) are then placed in test tubes which have plugs composed of stainless steel wire which keep the specimens immersed. 100 ml of xylene is charged to the test tubes, which are sealed with aluminum foil to prevent evaporation of the solvent. The xylene is then heated to the boiling point. The test specimens are kept in the boiling xylene for about 24 h. The gel-xylene mixture is then filtered by way of a sieve drum whose mesh width is 200 mesh, whereupon the gel remains in the sieve drum. The sieve drums are placed on metal plates and dried at 140° C. for 3 h in a convection oven. After cooling to room temperature, the contents are weighed and the ratio to the initial weight is calculated.

A particularly suitable plastics molding when using the novel production process is one with a three-dimensional surface structure, in particular a molded polymer skin or, respectively, foil with a grain on the surface, where the plastics molding is first subjected to preheating up to a temperature where the plastics molding becomes capable of thermoplastic deformation, and where the plastics molding is then pressed into/onto a female tool by way of subatmospheric pressure (i.e., vacuum forming) and/or of molding tools, where the surface of the female tool comprises the negative of the three-dimensional surface structure to be applied, the result being that the plastics molding not only receives the desired geometric shape but also is embossed with the desired positive surface structure, where the plastics molding has at least one plastics layer which, prior to the preheating and the thermoforming, or the surface-embossing process, is subjected to electron-beam crosslinking, where the plastics layer has in essence been crosslinked in those regions that face away from the subsequent grain side, and which therefore do not have, or have only to some extent, an embossed three-dimensional surface structure, where the plastics molding is composed of a thermoplastic elastomer, in particular of a thermoplastic olefin.

The particular advantage of using this type of polymer in the novel plastics molding is that the intermolecular crosslinking initially present in a thermo-plastic olefin (hydrogen bonds, crystalline structures) is predominantly thermally reversible and is in essence physical in nature, this being fundamental when considering suitability for the embossing process. The “additional” electron-beam crosslinking of certain layers of the polyolefin provides the particular and surprising raw-material property in which, after heating, on the one hand the thermoplastic behavior required for embossing is present and on the other hand there is sufficient heat resistance for reliable handling of the material in the process. For the first time, this also permits the use of foils composed of only one material, i.e. use of a “single-layer foil”.

The plastics molding is advantageously composed of crosslinked polymeric materials, in particular of a composition of polypropylene or of polyethylene, or of their copolymers and terpolymers. This provides for particular suitability for the production process, and also for application as, for example, grained molding for motor vehicle interiors.

In another advantageous embodiment, the plastics molding is a polymer foil or a multilayer polymer foil composite, where the constituents of the polymer foils are preferably composed of polyolefins.

There is in principle no restriction here on the range of polyolefins that can be used. Those that can be used with preference are polyolefins such as PP, PE, poly(1-butene), polyisobutylene, poly(4-methylpentene), PP copolymers or, respectively, terpolymers with C₂ or C₄-C₁₂-α-olefins, PE copolymers or, respectively, terpolymers with C₃ to C₁₂-α-olefins, or a mixture thereof, and the co- or termonomers used here can also comprise diene monomers which contain non-conjugated double bonds, e.g. 1,4-hexadiene, 5-methyl-1,5-hexadiene, 5-ethyl idene-2-norbornene, 5-butylidene-2-norbornene, dicyclopentadiene, 1,4-octadiene, cyclohexadiene, or cyclooctadiene; copolymers of propylene and/or ethylene with polar comonomers, such as acrylic acid, and/or C₁-C₁₂ esters thereof, methacrylic acid, and/or C₁-C₁₂-esters thereof, ionomers based on acrylic acid and/or with methacrylic acid or else sulfuric acid, with vinyl esters of saturated C₁-C₈ carboxylic acids, optionally with carbon monoxide as termonomer; graft copolymers of propylene and/or ethylene with from 8 to 45% of grafted-on units of unsaturated carboxylic acids, dicarboxylic acids, or their esters and/or anhydrides, or else a mixture of the polymers mentioned.

In another advantageous embodiment, the polymer foil or the multilayer polymer foil composite has, as an undermost layer, a foam layer, in particular composed of polyolefin foam. This provides access to further application sectors, in particular those in which, for example, the intention is to laminate a soft covering to a molding.

In another advantageous embodiment, the plastics molding has been provided, at least in its region facing away from the surface of the female tool, with a crosslinking aid, preferably with acrylates of monohydric alcohols or with methacrylates of mono- or polyhydric alcohols. This applies in particular to polyolefins, in which chain cleavage, which is a reaction proceeding in competition with crosslinking, has a marked effect. Polyolefins having tertiary and quaternary carbon atoms are particularly affected.

In another advantageous embodiment, the crosslinking aid is a trimethylolpropane triacrylate, trimethylolpropane trimethacrylate, triallyl cyanurate, or divinylbenzene. Vinyl-functional components are also suitable here for achieving precise and appropriately adjusted crosslinking, examples being styrene and divinylbenzene, allyl compounds, such as triallyl cyanurate and triallyl isocyanate, ethylene glycol dimethacrylate, diethylene glycol dimethacrylate, and/or polyethylene glycol dimethacrylate.

In another advantageous embodiment, the amount of crosslinking aid used in the respective foil sublayer is less than 10% by weight, in particular less than 5% by weight, and, in another preferred embodiment, less than 2%. These carefully judged additions of crosslinking aids are important when considering the different constitutions of the foils, i.e. the different polymers. For example, if there is high content of rubber which per se gives good crosslinking, the content of crosslinking aid is quite likely to be about 1.5%, whereas if there is high content of polypropylene, which gives rather poor crosslinking, a correspondingly higher content of crosslinking aid is to be provided.

The tables below use comparative examples to show the advantageous effect of the inventive process and the advantages of the inventive plastics molding. The upper region of the plastics molding composed of thermoplastic foil is then irradiated in an electron-beam crosslinking apparatus with the doses described in table 3, the foil here having in essence been crosslinked in those regions that face away from the subsequent grain side.

Comparative example 1 describes a foil structure which, by virtue of its low heat resistance, can be embossed very effectively with the desired grain in the in-mold-graining process, i.e. in the female-mold graining and thermoforming process, in a mold having the grain structure and geometry of the component in the form of a negative. However, the foil sags excessively (by more than 100 mm) during preheating to 200° C., the result often being creasing during the female-mold graining and thermoforming process.

In contrast, the sag in comparative example 2 is in the desired range of at most 100 mm. However, the grain introduced disappears at the selected heat-aging temperature typical of motor vehicle interiors. The reason for this is the excessive gel content of the foil, which induces what is known as the memory effect, which causes the polymer chains to reassume their position prior to reproduction of the grain.

A combination of good reproduction of the grain with little sag of the foil and very good thermal stability of the grain is provided only by the inventive foils and processing methods of embodiments 1 and 2.

Polymers Used
TPO: thermoplastic elastomer (not crosslinked), density 0.89 g/ml
MFI 1 g/10 min (230° C., 2.16 kg)

r-PP: random polypropylene copolymer, density 0.90 g/ml,
MFI 1 g/10 min (230° C., 2.16 kg)
LLDPE: linear low-density polyethylene, density 0.92 g/ml,
MFI 1 g/10 min (190° C., 2.16 kg)
VLDPE: very-low-density polyethylene, density 0.87 g/ml,
MFI 1 g/10 min (190° C., 2.16 kg)
EPDM: ethylene-propylene-diene copolymer, density 0.89 g/ml, diene content about 1% by weight.

TABLE 1
Foil compositions (proportions by weight)

| | Comparative | Comparative | | |
|---|---|---|---|---|
| | example 1 | example 2 | Embodiment 1 | Embodiment 2 |
| TPO | 75 | 75 | 40 | |
| r-PP | | | | 30 |
| LLDPE | | | 20 | 10 |
| VLDPE | 25 | 25 | | 50 |
| EPDM | | | 40 | 10 |

TABLE 2
Comparative examples and inventive embodiment

| | Comparative | Comparative | | |
|---|---|---|---|---|
| | example 1 | example 2 | Embodiment 1 | Embodiment 2 |
| Upper foil dose [Kmy] | 0 | 40 | 40 | 40 |
| Acceleration voltage | / | 400 KV | 650 KV | 900 KV |
| | | single-side | single-side | single-side |
| Capability for | 1 | 5 | 2 | 1 |
| reproduction of grain, | | | | |
| 1 min 170° C. (10 very | | | | |
| good, 50 poor) | | | | |
| Sag | 145 mm | 80 mm | 82 mm | 85 mm |
| 2 min, 200° C. | | | | |
| Gel content (%) | | | | |
| total | 0 | 23% | 30% | 22% |
| upper half of foil | 0 | 23% | 10% | 8% |
| Appearance of grain after | satisfactory | grain | satisfactory | satisfactory |
| 24 h, 120° C. | | flattened | | |

1. A method of producing thermoformable plastics moldings coming directly from the mold with a three-dimensional surface structure, the method which comprises:
preheating the plastics molding up to a temperature where the plastics molding becomes capable of thermoplastic deformation;
pressing the plastics molding into/onto a female tool, the female tool having a surface with a negative of the three-dimensional surface structure to be applied to the plastics molding, to thereby form the plastics molding into a desired geometric shape and to emboss a grain side of the plastics molding with the desired surface structure; and
subjecting the plastics molding to electron-beam crosslinking to thereby substantially crosslink only those parts of the plastics molding facing away from the grain side and that are therefore not embossed with the three-dimensional surface structure, or embossed only to a small extent.

2. The method according to claim 1, which comprises subjecting the plastics molding to the electron-beam crosslinking prior to or concurrently with at least one of the preheating step and the pressing step.

3. The method according to claim 1, which comprises forming molded polymer skins or foils with a surface grain.

4. The method according to claim 1, wherein the pressing step comprises molding the plastics molding into/onto the female tool by subjecting the plastic molding to at least one of a subatmospheric pressure and a molding tool.

5. The method according to claim 1, wherein the plastics molding is a layered product composed of one or more plastics foils each having a thickness between 0.4 mm and 4 mm.

6. The method according to claim 5, wherein the one or more plastic foils have a mutually identical polymeric constitution.

7. The method according to claim 5, wherein a gel content of that half of a foil web intended for embossing with the surface structure is at most 20%.

8. The method according to claim 7, wherein the gel content lies between 3% and 15%.

9. The method according to claim 7, wherein a total gel content of the foil lies between 5% and 60%.

10. The method according to claim 9, wherein the total gel content of the foil lies between 5% and 40%.

11. The method according to claim 7, wherein a difference in the gel content between an upper half and a lower half of the foil is at least 5%.

12. The method according to claim 11, wherein the difference in the gel content between the upper half and the lower half of the foil is substantially 10%.

13. A plastics molding with a three-dimensional surface structure, the plastics molding, after preheating to a temperature rendering the plastics molding capable of thermoplastic deformation, having been pressed into/onto a female tool in a vacuum-forming process by application of subatmospheric pressure and/or of one or more molding tools, the female tool having a surface formed with a negative of the three-dimensional surface structure to be applied, and the result being that the plastics molding not only receives the desired geometric shape but also is embossed with the desired positive surface structure, the plastics molding comprising:
a plastics molding body composed of a thermoplastic elastomer or of a polyolefin mixture;
said plastics molding body having a geometric shape dictated by the female tool and a surface embossed with the three-dimensional surface structure defined by the female tool;
said plastics molding body having at least one plastics layer cross-linked by electron-beam cross-linking prior to or during the preheating, the vacuum-forming process, or the surface-embossing process, the cross-linked plastics layer facing away from the surface of said plastics molding body embossed with the three-dimensional surface structure, and being substantially free of the embossed three-dimensional surface structure.

14. The plastics molding according to claim 13, consisting of a thermoplastic olefin.

15. The plastics molding according to claim 13, formed as a molded polymer skin or as a foil with a grain on the surface.

16. The plastics molding according to claim 13, wherein said plastics molding body is composed of crosslinked polymeric materials.

17. The plastics molding according to claim 16, wherein said plastics molding body is composed of a composition of polypropylene or of polyethylene, or of copolymers and terpolymers thereof.

18. The plastics molding according to claim 16, wherein said plastics molding body is a molding for a motor vehicle interior.

19. The plastics molding according to claim 13, wherein said plastics molding body is a polymer foil or a multilayer polymer foil composite.

20. The plastics molding according to claim 19, wherein said polymer foils are formed with polyolefins.

21. The plastics molding according to claim 19, wherein said polymer foil or said multilayer polymer foil composite carries a foam foil as an undermost layer.

22. The plastics molding according to claim 21, wherein said foam foil is a polyolefin foam.

23. The plastics molding according to claim 13, wherein said plastics molding body is provided, at least in a region of said cross-linked layer, with a crosslinking aid.

24. The plastics molding according to claim 23, wherein said crosslinking aid is selected from the group consisting of acrylates of monohydric alcohols and methacrylates of monohydric or polyhydric alcohols.

25. The plastics molding according to claim 23, wherein said crosslinking aid is selected from the group consisting of trimethylolpropane triacrylate, trimethylolpropane trimethacrylate, triallyl cyanurate, and divinylbenzene.

26. The plastics molding according to claim 23, wherein an amount of crosslinking aid used in the respective foil sublayer is less than 10% by weight.

27. The plastics molding according to claim 26, wherein the amount of cross-linking aid is less than 5% by weight.

28. The plastics molding according to claim 26, wherein the amount of cross-linking aid used in the respective foil sublayer is less than 2% by weight.
